(19) United States
(12) Patent Application Publication
(10) Pub. No.: US 2025/0297358 A1
(43) Pub. Date: Sep. 25, 2025

(54) SELF-PLANARIZING SELECTIVE CARBON GAPFILL DEPOSITION

(71) Applicant: Applied Materials, Inc., Santa Clara, CA (US)

(72) Inventors: Vamshi Krishna GADDAMEDI, Sunnyvale, CA (US); Tze-Yu LIN, Santa Clara, CA (US); Peiqi WANG, Campbell, CA (US); Anantha Venkataraman NAGARAJAN, Sunnyvale, CA (US); Abdul Aziz KHAJA, San Jose, CA (US)

(21) Appl. No.: 19/086,470

(22) Filed: Mar. 21, 2025

Related U.S. Application Data
(60) Provisional application No. 63/568,268, filed on Mar. 21, 2024.

(51) Int. Cl. C23C 16/04; C23C 16/26; C23C 16/505; C23C 16/56

(52) U.S. Cl. CPC C23C 16/045; C23C 16/26; C23C 16/505; C23C 16/56

(57) ABSTRACT

The present disclosure provides methods for forming a carbon gapfill layer. The methods include positioning a substrate having a top surface with at least two features disposed thereon on a substrate support in a processing volume. A hydrocarbon precursor gas is flowed into the processing volume. An etchant gas is flowed into the processing volume. A high frequency radio frequency (RF) power is provided to generate and maintain a RF plasma in the processing volume, where the high frequency RF power includes a frequency of about 10 MHz to about 40 MHz. A carbon gapfill layer is formed over the at least two features by using the RF plasma to concurrently deposit the deposition species on the substrate and etch the deposited deposition species using the etch species.

### CROSS-REFERENCE TO RELATED APPLICATION

The present Application claims priority to U.S. provisional application 63/568,268, filed Mar. 21, 2024, which is hereby incorporated by reference herein in its entirety.

### BACKGROUND

### Field

Embodiments of the present disclosure generally relate to manufacture of semiconductor components and devices. More specifically, embodiments described herein provide methods for forming even carbon gapfill layers on a semiconductor surface in trenches of varying sizes and/or aspect ratios.

### Description of the Related Art

In semiconductor processing, devices are being manufactured with continually decreasing feature dimensions. Often, features utilized to manufacture devices at these advanced technology nodes include high aspect ratio structures, and it is often necessary to fill gaps between circuit elements/structures with a variety of materials. Examples where gapfill material layers are utilized include filling shallow trench isolation (STI), horizontal interconnects, vias between adjacent metal layers, inter-metal dielectric layers (ILD), pre-metal dielectrics (PMD), passivation layers, patterning applications, etc. As the width between the structures shrink, the gap between them often gets taller and narrower, making the gap more difficult to fill without the gapfill material being stuck on sidewalls and creating voids and weak seams. Furthermore, oftentimes a single device or substrate will have multiple gaps of varying widths (e.g., critical dimensions (CD)) and/or aspect ratios that will need to be filled with the gapfill material.

Conventional chemical vapor deposition (CVD) techniques often experience an overgrowth of material at the top of the gap before it has been completely filled. This can create a void or seam in the gap where the depositing material has been prematurely cut off by the overgrowth; a problem sometimes referred to as bread-loafing. As device geometries shrink and thermal budgets are reduced, void-free and seam-free filling of high aspect ratio spaces becomes increasingly difficult due to limitations of existing deposition processes, especially for forming gapfill material layers to concurrently fill multiple gaps with different CDs and/or aspect ratios.

Accordingly, what is needed in the art are improved methods for forming gapfill material layers in trenches.

### SUMMARY

Embodiments described herein generally relate to processes for forming gapfill material layers. More specifically, embodiments described herein relate to processes for forming carbon gapfill layers using dual-frequency radiofrequency during deposition.

In one embodiment, the present disclosure provides methods for forming a carbon gapfill layer. The methods include positioning a substrate having a top surface with at least two features disposed thereon on a substrate support in a processing volume of a process chamber. A hydrocarbon precursor gas is flowed into the processing volume at a precursor flow rate for providing a deposition species. An etchant gas is flowed into the processing volume at an etchant flow rate for providing an etch species. A high frequency radio frequency (RF) power is provided to the processing volume to generate and maintain a RF plasma in the processing volume, wherein the high frequency RF power comprises a frequency of about 10 MHz to about 40 MHz. A carbon gapfill layer is formed over the at least two features by using the RF plasma to concurrently deposit the deposition species on the substrate and etch the deposited deposition species using the etch species.

In another embodiment, the present disclosure provides methods for forming a carbon gapfill layer. The methods include positioning a substrate having a top surface with at least two features disposed thereon on a substrate support in a processing volume of a process chamber. A deposition species is flowed into the processing volume. An etch species is flowed into the processing volume. A high frequency radio frequency (RF) power is provided to the processing volume to generate and maintain a RF plasma in the processing volume, wherein the high frequency RF power comprises a frequency of about 10 MHz to about 40 MHz. A carbon gapfill layer is formed over the at least two features by using the RF plasma to concurrently deposit the deposition species on the substrate and etch the deposition species using the etch species. The RF plasma is maintained for a time period to form the carbon gapfill layer in a trench between the two or more features having a maximum vertical height difference of about 1 nm to about 10 nm.

In another embodiment, the present disclosure provides methods for forming a carbon gapfill layer. The methods include positioning a substrate having a top surface with at least two features disposed thereon on a substrate support in a processing volume of a process chamber. A hydrocarbon precursor gas is flowed into the processing volume at a precursor flow rate for providing a deposition species. An etchant gas is flowed into the processing volume at an etchant flow rate for providing an etch species. A high frequency radio frequency (RF) power is provided to the processing volume to generate and maintain a RF plasma in the processing volume, wherein the high frequency RF power comprises a frequency of about 10 MHz to about 40 MHz. A carbon gapfill layer is formed over the at least two features by using the RF plasma to concurrently deposit the deposition species on the substrate and etch the deposited deposition species using the etch species. Etching the deposited deposition species using the etch species includes etching a deposited deposition species on a top surface of the at least two features.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a process chamber, according to certain embodiments;

FIG. 2 is a schematic block diagram of a method for forming a carbon gapfill layer, according to certain embodiments;

FIGS. 3A-3C are partial schematic side cross-sectional views of a substrate during the method of FIG. 2, according to certain embodiments;

FIGS. 4A-4C are partial schematic side cross-sectional views of a substrate during the method of FIG. 2, according to certain embodiments.

FIG. 5 is a graph of a change in Gibbs free energy over a reaction time, according to certain embodiments;

FIG. 6 is a graph of a rate of production at different electron temperatures, according to certain embodiments;

FIG. 7 is a partial schematic side cross-sectional view of a substrate during processing, according to certain embodiments;

FIGS. 8A and 8B are graphs of a C₂H and H total source over a total distance of a substrate, according to certain embodiments; and

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The following disclosure describes techniques for forming gapfill material layers in features, such as trenches formed on a substrate or a material layer disposed thereon. Certain details are set forth in the following descriptions and figures to provide a thorough understanding of various embodiments of the disclosure. Other details describing well-known structures and systems often associated with chemical vapor deposition (CVD) processing are not set forth in the following disclosure to avoid unnecessarily obscuring the description of the various embodiments.

Many of the details, dimensions, angles and other features shown in the figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

Embodiments described herein will be described below in reference to a CVD deposition process that can be carried out using any suitable thin film deposition system. Examples of suitable systems include the CENTURA® systems which may use a DXZ® process chamber, PRECISION 5000@ systems, PRODUCER® systems, PRODUCER® GT™ systems, PRODUCER® XP Precision™ systems, PRODUCER® SE™ systems, Sym3® process chamber, and Mesa™ process chamber, all of which are commercially available from Applied Materials, Inc., of Santa Clara, California.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface.

In addition to film processing directly on the surface of the substrate itself, in the present disclosure, any of the processing steps disclosed may also be performed on an intermediate layer formed on the substrate as disclosed in more detail below, and the term “substrate surface” is intended to include such intermediate layer as the context indicates. Thus, for example, where a film/layer or partial film/layer has been deposited onto a substrate surface, the exposed surface of the newly deposited film/layer becomes the substrate surface.

Carbon-based film deposition has been used to provide gapfill material layers during semiconductor processing through vapor deposition process techniques, such as CVD or plasma enhanced chemical vapor deposition (PECVD). Most vapor deposition methods, including CVD and PECVD, utilize a blanket deposition process that generally deposits more gapfill material along a top surface of a feature, where a trench between the features remains void of the gapfill material layer.

Embodiments of the present disclosure provide techniques for performing a deposition with the use a high frequency radio frequency (HFRF), e.g., about 10 MHz to about 40 MHz, to form a substantially planar carbon gapfill layer in a trench between adjacent vertical structures having varying critical dimensions, e.g., critical dimensions from about 8 nm to about 1000 nm, e.g., about 8 nm to about 800 nm, about 100 nm to about 600 nm, about 200 nm to about 400 nm, or about 250 nm to about 350 nm, about 8 nm to about 50 nm, about 50 nm to about 100 nm, about 100 nm to about 150 nm, about 150 nm to about 200 nm, about 200 nm to about 250 nm, about 250 nm to about 500 nm, or about 500 nm to about 1000 nm. In some embodiments, the use of HFRF during deposition of a hydrocarbon deposition species can assist in forming a planar carbon gapfill layer that is substantially uniform across the features. Without being bound by theory, the growth profile of the carbon gapfill layer in each of the trenches may be more uniform when using HFRF as compared to conventional carbon gapfill processes.

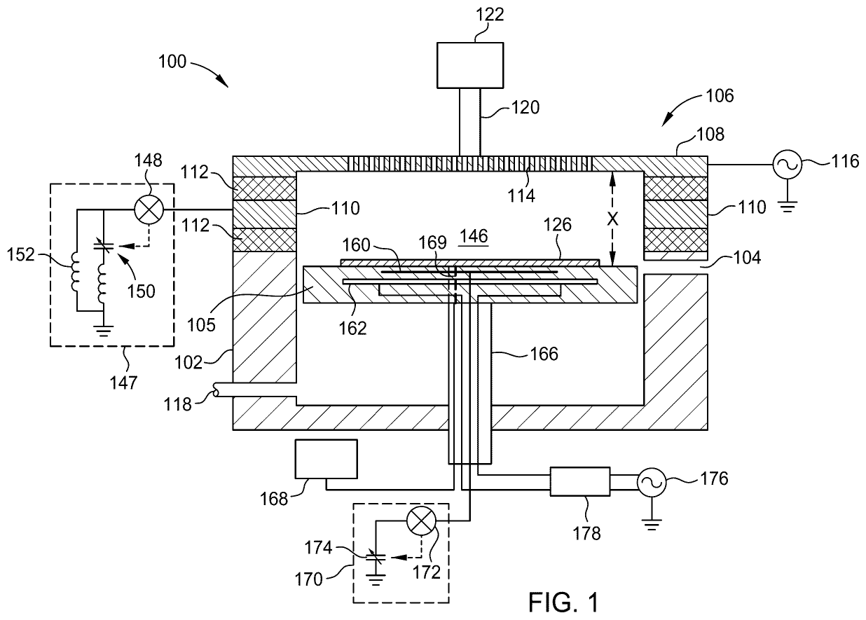

FIG. 1 is a schematic cross sectional view of a process chamber 100 configured according to various embodiments of the present disclosure. By way of example, the embodiment of the process chamber 100 in FIG. 1 is described in terms of a PECVD system, but any other process chamber may fall within the scope of the embodiments, including other plasma deposition chambers or plasma etch chambers. The process chamber 100 includes a chamber body 102, a lid assembly 106, and a substrate support 105. The lid assembly 106 is disposed at an upper end of and is supported by the chamber body 102, and the substrate support 105 is at least partially disposed within the chamber body 102. The chamber body 102, lid assembly 106, and substrate support 105 together define an processing volume 146 within the process chamber 100 in which a substrate may be processed. The processing volume 146 may be accessed through a port 104 formed in the chamber body 102 that facilitates transfer of a substrate into and out of the processing volume 146 of the process chamber 100.

The lid assembly 106 includes a gas distributor 108, a modulation electrode 110, and insulators 112. The insulator 112, which may be a dielectric material such as a ceramic or metal oxide, for example aluminum oxide and/or aluminum nitride, contacts the modulation electrode 110 and separates the modulation electrode 110 electrically and thermally from the gas distributor 108 and from the chamber body 102. The gas distributor 108 (e.g., showerhead) has passages 114 therethrough for admitting process gas into the processing volume 146. A pair of insulators (e.g., annular insulators) are disposed between the gas distributor 108 and the modulation electrode 110. The modulation electrode 110 is annular and circumscribes the processing volume 146.

Process gases (e.g., one or more precursor and one or more inert carrier gas) may be provided through the conduit 120 from a gas source 168 to be introduced into the process chamber 100. The processing gas from the conduit 120 enters the processing volume 146 through the passages 114 in the gas distributor 108 such that the processing gas is uniformly distributed in the processing volume 146. In one embodiment, the passages 114 in the gas distributor 108 may be radially distributed and gas flow to each of the passages 114 may be separately controlled to further facilitate gas uniformity within the processing volume 146.

The processing gases can be evacuated from the processing volume 146 through an outlet 118 which may be located at any convenient location along the chamber body 102. In some embodiments, the outlet 118 may be associated with a vacuum pump (not shown) fluidly coupled to the processing volume 146. The vacuum pump may be part of the gas and pressure control system of the processing chamber 100.

In some embodiments, portions of the gas distributor 108 may be heated using a resistive heater (not shown) or thermal fluid disposed in a conduit (not shown) through a portion of the gas distributor 108 or otherwise in direct contact or thermal contact with the gas distributor 108. The conduit may be disposed through an edge portion of the gas distributor 108 to avoid disturbing the gas flow function of the gas distributor 108. Heating the edge portion of the gas distributor 108 may be useful to reduce the tendency of the edge portion of the gas distributor 108 to be a heatsink within the process chamber 100.

In some embodiments, the walls of the chamber body 102 may also be heated to similar effect. Heating the chamber surfaces exposed to the plasma also minimizes deposition, condensation, and/or reverse sublimation on the chamber surfaces, reducing the cleaning frequency of the chamber and increasing mean cycles per clean. Higher temperature surfaces also promote dense deposition that is less likely to produce particles that fall onto a substrate. Thermal control conduits with resistive heaters and/or thermal fluids (not shown) may be disposed through the chamber walls to achieve thermal control of the chamber walls. Temperature of all surfaces may be controlled by a controller.

In some embodiments, the gas distributor 108 may be coupled to a RF power source 116, such as a RF generator, as shown in FIG. 1. DC power, pulsed DC power, and pulsed RF power source may alternatively be used. In other embodiments, the gas distributor 108 may be coupled to ground. The RF power source 116 is electrically connected to the gas distributor 108 and is configured to apply a RF potential to the gas distributor 108 to facilitate the generation of plasma in the processing volume 146. In some embodiments, the RF power source 116 may be a high frequency RF power source (“HFRF power source”) capable of generating an HFRF power (e.g., at a frequency of about 10 MHz to about 40 MHz, e.g., about 20 MHz to about 22 MHZ, about 22 MHz to about 24 MHZ, about 24 MHz to about 26 MHz, about 26 MHz to about 28 MHz, or about 28 MHz to about 30 MHZ). In other embodiments, the RF power source 116 may be a low frequency RF power source (“LFRF power source”) capable of generating an LFRF power (e.g., at a frequency of about 300 kHz). The LFRF power source can provide both low frequency generation and fixed match elements. The HFRF power source can be designed for use with a fixed match and can regulate the power delivered to the load, eliminating concerns about forward and reflected power. Without being bound by theory, an HFRF power source of about 26 MHz to about 28 MHz can provide an increase in the C₂H production rate and H production rate, thereby producing a more conformal and/or uniform carbon gapfill in trenches between one or more features, and reducing pattern loading effects.

In further embodiments, an additional power source (not shown) may be added with the RF power source 116 to provide a dual RF power source to the process chamber 100. The modulation electrode 110 may be coupled to a tuning circuit 147 that controls an impedance of an electrical path from the modulation electrode 110 to an electrical ground. The tuning circuit 147 comprises an electronic sensor 148 and an electronic controller, which may be a variable capacitor 150 as shown that is controllable by the electronic sensor 148. The tuning circuit 147 may be an LLC circuit comprising one or more inductors 152. The electronic sensor 148 may be a voltage or current sensor and may be coupled to the variable capacitor 150 to afford a degree of closed-loop control of plasma conditions inside the processing volume 146. In some embodiments, the tuning circuit 147 may be any circuit that features a variable or controllable impedance under the plasma conditions present in the processing volume 146 during processing

The substrate support 105 may be disposed within the process chamber 100. The substrate support 105 may support a substrate 126 during processing. A first electrode 160 and a second electrode 162 are disposed in and/or on the substrate support 105. Further, in some embodiments, a heater element (not shown) may be embedded in the substrate support 105. The heater element can be operable to controllably heat the substrate support 105 and the substrate 126 positioned thereon to a target temperature, such as to maintain the substrate 126 at a temperature in a range from about 350 degrees Celsius to about 500 degrees Celsius.

The substrate support 105 is coupled to a shaft 166 for support. The shaft 166 can provide a conduit from a gas source 168 and electrical and temperature monitoring leads (not shown) between the substrate support 105 and other components of the process chamber 100. In some examples, a purge gas may be provided from the gas source 168 to the backside of the substrate 126 through one or more purge gas inlets 169 connected to the substrate support 105. The purge gas flowed toward the backside of the substrate 126 can help prevent particle contamination caused by deposition on the backside of the substrate 126. The purge gas may also be used as a form of temperature control to cool the backside of the substrate 126. Although not illustrated, the shaft 166 may be coupled to an actuator (not shown) which extends through a centrally-located opening formed in a bottom of the chamber body 102. The actuator may be flexibly sealed to the chamber body 102 by bellows (not shown) that prevent vacuum leakage from around the shaft 166. The actuator can allow the substrate support 105 to be moved vertically within the chamber body 102 between a process position and a lower, transfer position. The transfer position is slightly below the port 104 in the chamber body 102. In operation, the substrate support 105 may be elevated to a position in close proximity to the lid assembly 106 for processing.

The first electrode 160 may be embedded within the substrate support 105 or coupled to a surface of the substrate support 105. The first electrode 160 may be a plate, a perforated plate, a mesh, a wire screen, or any other distributed arrangement. The first electrode 160 may be a tuning electrode and may be coupled to a tuning circuit 170. The tuning circuit 170 may have an electronic sensor 172 and an electronic controller, such as a variable capacitor 174 electrically connected between the first electrode 160 and an electrical ground. The electronic sensor 172 may be a voltage or current sensor and may be coupled to the variable capacitor 174 to provide further control over plasma conditions in the processing volume 146.

The second electrode 162, which may be a bias electrode and/or an electrostatic chucking electrode, may be coupled to the substrate support 105. The second electrode 162 may be coupled to a bias power source 176 through an impedance matching circuit 178. The bias power source 176 may be DC power, pulsed DC power, RF power, pulsed RF power, or a combination thereof.

In operation, the substrate 126 is disposed on the substrate support 105, and process gases are flowed through the lid assembly 106 according to any desired flow plan. Electric power is coupled to the gas distributor to establish a plasma in the processing volume 146. The substrate 126 may be subjected to an electrical bias using the bias power source 176, if desired.

Upon energizing a plasma in the processing volume 146, a potential difference is established between the plasma and the modulation electrode 110. A potential difference is also established between the plasma and the first electrode 160. The variable capacitors 150 and 174 may then be used to adjust the impedances of the paths to an electrical ground represented by the tuning circuits 144 and 170. A set point may be delivered to the tuning circuit 144 and 170 to provide independent control of the plasma density uniformity from center to edge and deposition rate. The electronic sensors may adjust the variable capacitors to maximize deposition rate and minimize thickness non-uniformity independently. The components implemented to control temperature and uniformity of the plasma, among other, can permit deposition of a highly conformal layer on a substrate being processed, even within small gaps.

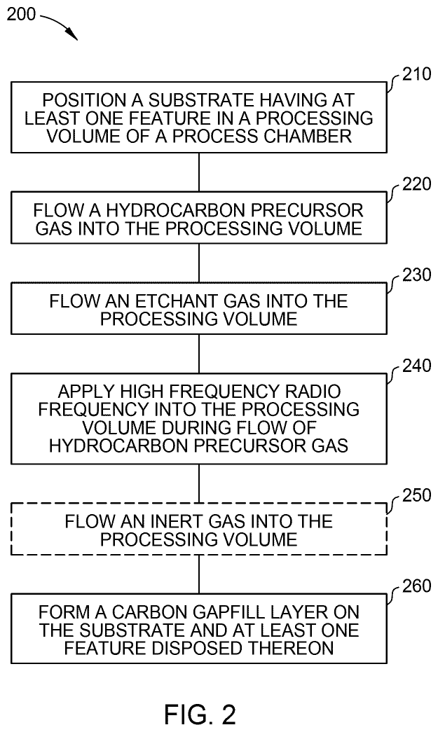

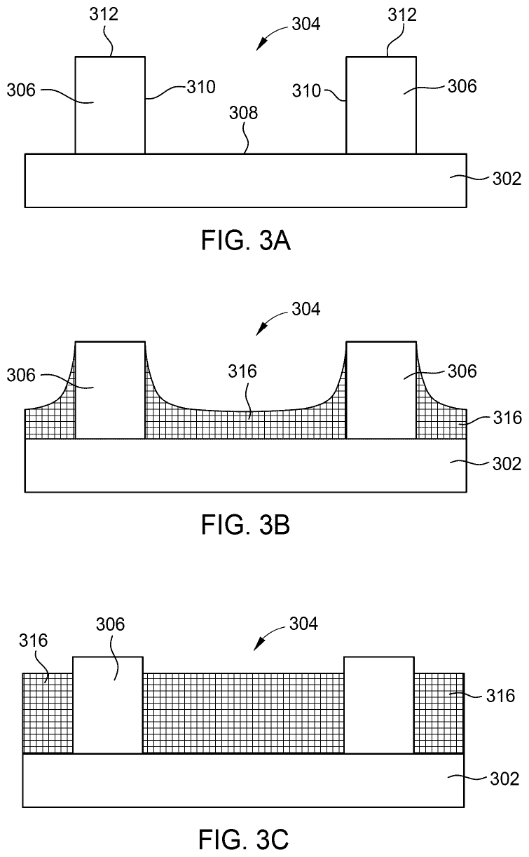

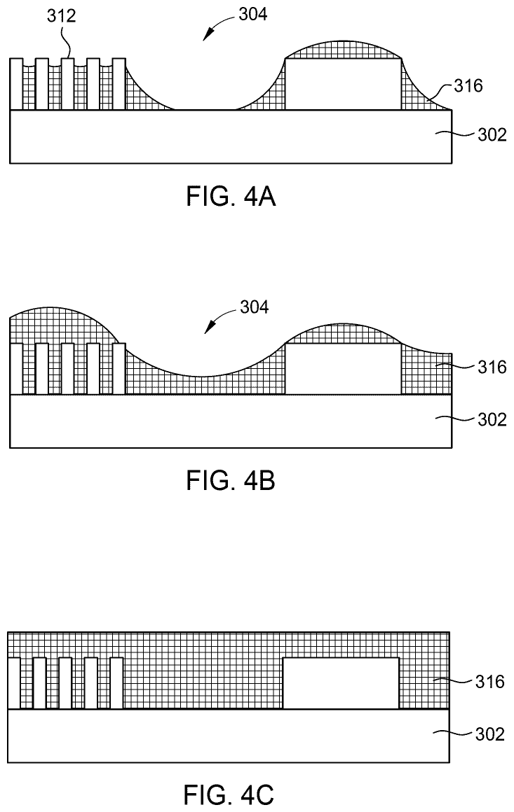

FIG. 2 depicts a process flow diagram of a method 200, for forming a carbon gapfill layer in a feature formed on a substrate 302, in accordance with one or more embodiments of the present disclosure. FIG. 3A, FIG. 3B, and FIG. 3C depict schematic cross-sectional views of a substrate structure illustrating the carbon gapfill layer formation sequence according to method 200. FIG. 4A, FIG. 4B, and FIG. 4C depict schematic cross-sectional views of a substrate structure illustrating the carbon gapfill layer formation sequence according to method 200. As used in this regard, the term “feature” means any intentional surface irregularity. The shape of the feature can be any suitable shape including, but not limited to, trenches cylindrical vias. Suitable examples of features include, but are not limited to trenches which two sidewalls and a bottom surface, and vias which have a generally cylindrical sidewall. Other examples of features include without limitation, lines, contact holes, through-holes or other feature definitions utilized in a semiconductor, solar, or other electronic devices, such as high ratio contact plugs. The features can have any suitable aspect ratio (ratio of the depth of the feature to the width of the feature), e.g., about 22:1 to about 0.5:1.

Although the method 200 is described below with reference to forming a carbon gapfill layer in a trench between structures formed on a substrate, the method 200 may also be used to advantage in other device manufacturing applications. Further, it should also be understood that the operations depicted in FIG. 2 may be performed simultaneously and/or in a different order than the order depicted in FIG. 2.

The method 200 begins at operation 210 by positioning a substrate 302, into a processing volume of a process chamber, such as the processing volume 146 of the process chamber 100 depicted in FIG. 1. The substrate 302 may be the substrate 126 depicted in FIG. 1. As show in FIG. 3A and FIG. 3B, the substrate 302 includes at least one feature, such as a trench 304 formed between a pair of vertical structures 306 disposed on the substrate 302. The trench 304 includes a bottom surface 308 between sidewalls 310, and an opening between top surfaces 312 of each of the vertical structures 306. In some embodiments, the trench 304 may be a negative feature formed directly in the substrate 302. Although FIG. 3A and FIG. 3B show substrate 302 having a single trench 304 for illustrative purposes, those skilled in the art will understand that there can be more than one trench 304, each with the same or different CDs.

While the substrate 302 is illustrated as a single body, it is understood that the substrate 302 may contain one or more materials used in forming semiconductor devices such as metal contacts, trench isolations, gates, bitlines, or any other interconnect features. The substrate 302 may comprise one or more metal layers, one or more dielectric materials, semiconductor material, and combinations thereof utilized to fabricate semiconductor devices. For example, the substrate 302 may include an oxide material, a nitride material, a polysilicon material, or the like, depending upon application. The substrate 302 may be any substrate or material surface upon which film processing is performed. For example, the substrate 302 may be a material such as crystalline silicon, silicon oxide, silicon oxynitride, silicon nitride, strained silicon, silicon germanium, tungsten, titanium nitride, doped or undoped polysilicon, doped or undoped silicon wafers and patterned or non-patterned wafers, silicon on insulator (SOI), carbon doped silicon oxides, silicon nitrides, doped silicon, germanium, gallium arsenide, glass, sapphire, low-k dielectrics, and combinations thereof.

In an embodiment, the substrate, e.g., substrate 302, is transferred into the process chamber 100 and onto the substrate support 105 by any suitable means, such as by substrate transfer port (not shown). The substrate support 105 can be adjusted to a processing position by an actuator (not shown). In some embodiments, the position of the substrate support 105 and the substrate 302 in the processing volume 146 may be changed such that the substrate 302 may be moved towards the gas distributor 108, and the spacing between the bottom surface of the gas distributor 108 and a top surface of the substrate support 105 is between about 200 mils and about 1,000 mils.

At operation 220, a hydrocarbon precursor gas is flowed into the processing volume 146. In an embodiment, the hydrocarbon precursor gas may be flowed from the gas source 122 into the processing volume 146 through the gas distributor 108. The hydrocarbon precursor may be flowed from the gas source 122 into the processing volume 146 at a flow rate of about 200 sccm to about 500 sccm, e.g., about 200 sccm to about 350 sccm, about 350 sccm to about 400 sccm, about 400 sccm to about 450 sccm, or about 450 sccm to about 500 sccm.

During processing, the hydrocarbon precursor gas may be used to provide a deposition species for forming the carbon gapfill layer. In an embodiment, the hydrocarbon precursor gas includes a hydrocarbon compound having a general formula CₓH_{y}, where x has a range of between 1 and 20 and y has a range of between 1 and 20. Suitable carbon compounds include, for example, methane (CH₄), ethylene (C₂H₄), ethane (C₂H₆), butylenes (C₄H₈), cyclobutane (C₄H₈), and methylcyclopropane (C₄H₈). Suitable butylenes include, for example, 1-Butene, 2-Butene, and isobutylene. In certain embodiments, the hydrocarbon source can be a liquid or gas. In one embodiment, the hydrocarbon precursor gas includes acetylene (C₂H₂). In another embodiment, the hydrocarbon precursor gas includes propylene (C₃H₆). In one example, the hydrocarbon precursor gas is vapor at room temperature, which simplifies the hardware for material metering, control, and delivery to the process chamber.

In some embodiments, the hydrocarbon precursor gas may further include a dilution gas. Suitable dilution gases such as helium (He), argon (Ar), or combinations thereof, may be added to the hydrocarbon precursor gas. Alternatively, dilution gases may not be used during the deposition. For example, the dilution gas can include a combination of He and Ar, where about 0 sccm to about 500 sccm of He is flowed into the processing volume 146, e.g., about 0 sccm to about 150 sccm, about 150 sccm to about 200 sccm, about 200 sccm to about 250 sccm, about 250 sccm to about 300 sccm, or about 300 sccm to about 500 sccm, and about 2000 sccm to about 5000 sccm of Ar is flowed into the processing volume 146, e.g., about 3300 sccm to about 3400 sccm or about 3400 sccm to about 3500 sccm.

At an operation 230, an etchant gas may be flowed into the process chamber 100. In certain embodiments, the etchant gas may be flowed from the gas source 122 into the processing volume 146 through the gas distributor 108. In some embodiments, the flow of the etchant gas may occur simultaneously to the flow of the hydrocarbon precursor gas. In an embodiment, the etchant gas includes hydrogen gas (H₂) for providing H* radicals to etch portions of the carbon gapfill layer 316 deposited during processing. In other embodiments, the etchant gas may be CO₂ or NHs gas. In some embodiments, the flow rate of the etchant gas may range from about 300 sccm to about 1000 sccm, e.g., about 300 sccm to about 500 sccm, about 500 sccm to about 700 sccm, about 700 sccm to about 900 sccm, or about 800 sccm to about 1000 sccm. The etchant gas may be flowed into the processing volume to provide a hydrocarbon precursor gas to etchant gas ratio of about 0.01 to about 0.05, e.g., about 0.01 to about 0.02, about 0.02 to about 0.03, about 0.03 to about 0.04, or about 0.04 to about 0.05. Without being bound by theory, a higher ratio of hydrocarbon precursor gas to etchant gas may result in a gapfill material capable of planarizing such that a uniform gapfill material exists, thereby reducing pattern loading effects.

At operation 240, a high frequency RF power is applied to the process chamber 100 to ignite and generate a RF plasma in the processing volume 146. The high frequency RF may be provided by an RF power source 116 to facilitate generation of the RF plasma. In an embodiment, the high frequency RF power includes a HFRF power. In certain embodiments, the HFRF power is maintained during the deposition of a hydrocarbon deposition species. In certain embodiments, the HFRF power may be maintained during processing in a range between about 800 W and about 3000 W, e.g., about 800 W to about 1000 W, about 1000 W to about 1200 W, about 1200 W to about 1400 W, about 1400 W to about 1500 W, about 1500 W to about 2000 W, or about 2000 W to about 3000 W. In certain embodiments, the HFRF power may operate at a frequency of 10 MHz to about 40 MHz, e.g., about 20 MHz to about 22 MHz, about 22 MHz to about 24 MHz, about 24 MHz to about 26 MHZ, about 26 MHz to about 28 MHZ, or about 28 MHz to about 30 MHz.

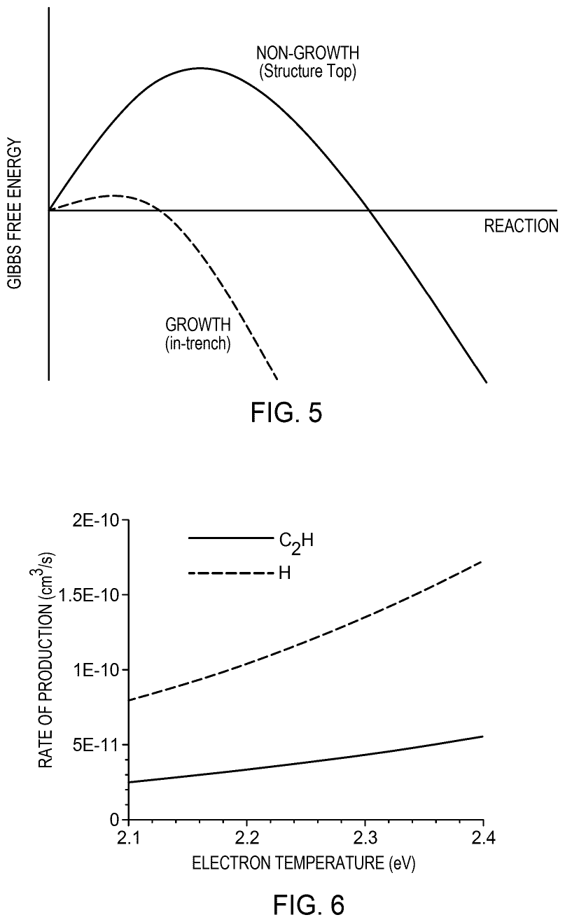

In an embodiment, the high frequency RF power may provide a total ion flux of about 1.0×10²⁰ m⁻²s⁻¹ to about 1.3×10²⁰ m⁻²s⁻¹. Without being bound by theory, a higher ion energy can result in a higher sheath potential, which may prevent hydrocarbon precursor gas deposition at a top surface 312 of the feature due to producing a higher Gibbs free energy at the top surface 312 of the feature compared to the trench 304, as shown in FIG. 5. Without being bound by theory, a higher Gibbs free energy at the top surface 312 of the feature compared to the trench 304 may provide enhanced deposition at the bottom of the trench and concurrent enhanced etching at the top surface 312 of the feature due to the reduced number of active sites along the top surface 312 of the feature compared to the active sites along the trench 304. In an embodiment, the high frequency RF power may provide a sheath potential of about 100 V to about 150 V, e.g., about 100 V to about 110 V, about 110 V to about 120 V, about 120 V to about 130 V, about 130 V to about 140 V, or about 140 V to about 150 V. Without being bound by theory, a sheath potential of about 100 V to about 150 may provide confinement of etchant gases, e.g., H ions, to a top surface 312 of the feature, thereby allowing deposition of the hydrocarbon precursor gas to be selective to the trench 304 due to the reduced Gibbs free energy at the trench 304 compared to the top surface 312 of the feature.

In an embodiment, the high frequency RF power may provide an electron temperature of about 2.2 eV to about 2.5 eV, e.g., about 2.2 eV to about 2.3 eV, about 2.3 eV to about 2.4 eV, or about 2.4 eV to about 2.5 eV. Without being bound by theory, an electron temperature of about 2.2 eV to about 2.5 eV may provide an increasing temperature of the top surface 312 of the feature, compared to the bottom surface 308, thereby increasing etching at the top surface 312 of the feature compared to the bottom surface 308. An electron temperature of about 2.2 eV to about 2.5 eV may provide an increased production of C₂H and H, as shown in FIG. 6. Without being bound by theory, an increased production of C₂H and H may increase selective deposition of the hydrocarbon precursor gas in the trench 304 compared to the top surface 312 of the feature.

At an optional operation 250, an inert gas, such as argon may be supplied with the hydrocarbon precursor gas into the process chamber 100. In some embodiments, the flow rate of the argon gas may range from about 0 sccm to about 5,000 sccm. In some embodiments, argon may optionally be used for additional control over the deposition rate of the carbon gapfill layer. For example, when the carbon gapfill layer is being formed in multiple trenches of varying CDs, the deposition rate in trenches may vary as a result of the different CDs. Accordingly, argon may therefore be used to increase the deposition rate and provide for a more uniform deposition rate when depositing in multiple trenches with non-uniform CDs. In some embodiments, the addition of argon may also further assist in increased etching of deposition on the top surface 312 of the vertical structures 306 to reduce or minimize top-hat formation.

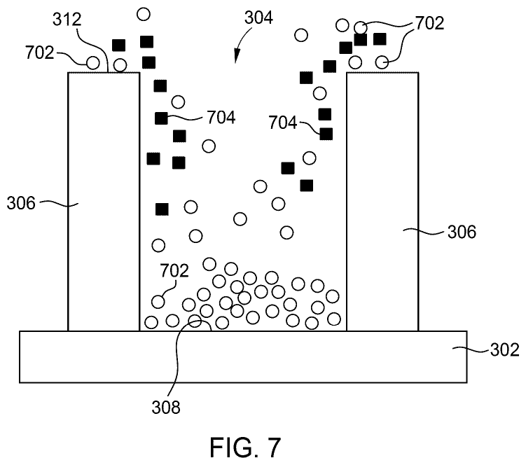

At operation 260, a carbon gapfill layer 316 is formed in the trench 304 on the substrate 302 using the RF plasma generated in operation 240, as shown in FIG. 3B and FIG. 4A. The carbon gapfill layer 316 may form at greater rates in the trench 304 between the vertical structures 306 of the substrate 302 compared to the top surface 312 of the feature. In an embodiment, the plasma may be formed by capacitive means, and may be energized by coupling RF power into the processing gas mixture provided in operations 220-240. The plasma generated in operation 260, as seen in FIG. 7, is correspondingly used to simultaneously deposit and etch the carbon gapfill layer on the substrate 302. During processing, the disassociation of the hydrocarbon precursors in the plasma results in the deposition of deposition species 702 (e.g., C₂H₂⁺ or hydrocarbon ions) on the substrate 302, including the bottom surface 308 of the trench 304 and on the top surfaces 312 of the vertical structures 306. The plasma generated from the processing gases simultaneously also causes disassociation of the etchant gas resulting in etching species 704 (e.g., hydrogen radicals) that etch portions of the carbon gapfill layer deposited on the sidewalls 310 and the top surface 312 of the vertical structures 306 near the opening of the trench 304. The etching by the hydrogen radicals minimizes deposition on top of the vertical structures 306 near the opening of the trench 304, thereby preventing formation of top-hats on the vertical structures 306. The etching by the hydrogen radicals also prevents deposition on the sidewalls 310 within the trench 304 thereby preventing bread-loafing from occurring. This results in a more uniform deposition across the surface of the substrate 302, effectively acting in a self-planarizing manner.

During formation of the carbon gapfill layer 316, the process chamber 100, the substrate 302, or both may be maintained at a temperature of about 350 degrees Celsius and about 500 degrees Celsius, e.g., about 400 degrees Celsius to about 500 degrees Celsius or about 450 degrees Celsius to about 500 degrees Celsius. Without being bound by theory, an elevated temperature may result in increased etching of the substrate compared to a lower temperature. Additionally, and without being bound by theory, an elevated temperature may be independent of a growth of a hydrocarbon precursor gas compared to a lower temperature. The chamber pressure may range from about 1 Torr to about 50 Torr, e.g., about 1 Torr to about 10 Torr, about 10 Torr to about 20 Torr, about 20 Torr to about 30 Torr, or about 30 Torr to about 50 Torr. Without being bound by theory, a chamber pressure of about 40 Torr to about 50 Torr may decrease the mean free path, thereby preventing radicals from entering the trench 304. The distance between the substrate support 105 and gas distributor 108, e.g., spacing in FIG. 1, may be set to between about 200 mils and about 600 mils, for example, about 400 mils.

The plasma can be maintained for a time period to form the carbon gapfill layer 316 in the trench 304, as shown in FIG. 4B. The process of operation 260 may be performed simultaneously, sequentially or may partially overlap with the processes of operations 220-250. In some embodiments, the flow of each of the processing gases (e.g., the hydrocarbon precursor gas and the etchant gas) may be stopped when each of the trench 304 is sufficiently filled, as shown in FIG. 4C. In some embodiments, the carbon gapfill material can planarize during the trench being filled and/or after the trench 304 is filled, thereby reducing the need for, and possibly even avoid altogether, any subsequent chemical mechanic polishing (CMP) process to prepare and flatten the surface for forming of subsequent optical structures, as shown in FIG. 4C. Without being bound by theory, the carbon gapfill material can planarize to produce a topography of the carbon gapfill layer having a maximum vertical height difference of about 1 nm to about 10 nm, e.g., about 1 nm to about 2 nm, about 2 nm to about 3 nm, about 3 nm to about 4 nm, or about 4 nm to about 10 nm. In some embodiments, the flow of each of the processing gases may be stopped when the carbon gapfill layer 316 above the trench 304 is sufficiently planarized. Any excess process gases and by-products from the deposition of the season layer may then be removed from the processing volume by performing an optional purge/evacuation process.

### EXAMPLES

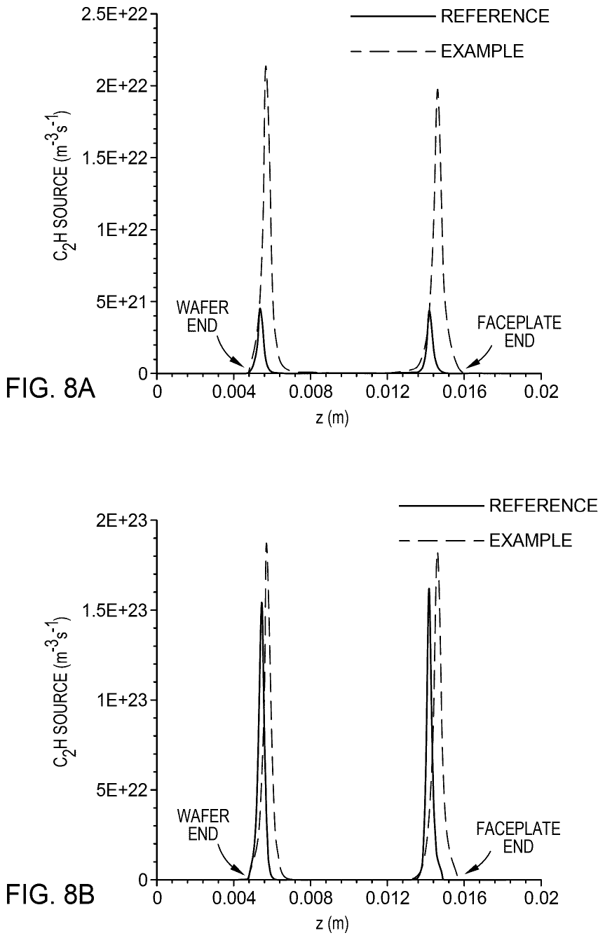

A planarizing carbon gapfill process utilizing a 13 MHz RF generator (reference process) was compared to a planarizing carbon gapfill process utilizing a 27 MHz RF generator (example process). The example process had a higher C₂H₂ density, C₂H production rate, C₂H total source, and electron temperature, as shown in FIG. 8A and Table 1.

TABLE 1

| Property | Reference | Example |
|---|---|---|
| e⁻ density (m⁻³) | 4.68E+16 | 3.33E+16 |
| C₂H₂ density (m⁻³) | 1.60E+21 | 4.74E+21 |
| e⁻ temp. (eV) | 2.134 | 2.365 |
| C₂H production rate (cm³/s) | 5.58E−11 | 1.02E−10 |
| C₂H total source (m⁻³/s) | 4.54E+21 | 2.14E+22 |

An increased electron temperature, C₂H production rate and C₂H total source, can provide a reduction of deposition at a top surface of a feature due to a reduction in the number of active sites along a top surface of the feature.

Moreover, the example process had a lower H₂ density, but a higher H₂ production rate, H₂ total source, and electron temperature, as shown in FIG. 8B and Table 2.

TABLE 2

| Property | Reference | Example |
|---|---|---|
| e⁻ density (m⁻³) | 4.20E+16 | 3.33E+16 |
| H₂ density (m⁻³) | 2.18E+22 | 1.42E+22 |
| e⁻ temp. (eV) | 2.112 | 2.364 |
| H production rate (cm³/s) | 8.17E−11 | 1.58E−10 |
| H total source (m⁻³/s) | 1.55E+23 | 1.88E+23 |

A higher H production rate led to passivation of the top surface of the feature, thereby minimizing growth of C₂H on the top surface, allowing for selective deposition of carbon gapfill material in the trenches between two or more features. Moreover, by increasing the C₂H to H radical/ion flux ratio, an increase in the H etching occurred at the top surface of the feature, allowing the H to produce a greater planarizing effect.

Overall, the present disclosure provides techniques for performing a carbon gapfill process using a high frequency radio frequency, e.g., about 10 MHz to about 40 MHz, to form a substantially planar carbon gapfill layer in a trench between adjacent vertical structures having varying critical dimensions, The high frequency RF power (HFRF) power provides an increased C₂H and H production rate, as well as an increased electron temperature, thereby increasing the rate of selective deposition of a hydrocarbon precursor gas in a trench, while mitigating growth along a top surface of a feature of the substrate. Moreover, the HFRF can selectively fill trenches such that a planar carbon gapfill layer is produced that is substantially uniform across all of the features, e.g., having a difference in a maximum height to a maximum depth from about 1 nm to about 10 nm. The HFRF can produce a self-limiting carbon gapfill process that produces a uniform carbon gapfill material, reducing pattern loading effects in the process.

While the foregoing is directed to embodiments of the present disclosure, other and further embodiments of the disclosure may be devised without departing from the basic scope thereof, and the scope thereof is determined by the claims that follow.

What is claimed is:

1. A method for forming a carbon gapfill layer, comprising:
positioning a substrate having a top surface with at least two features disposed thereon on a substrate support in a processing volume of a process chamber;
flowing a hydrocarbon precursor gas into the processing volume at a precursor flow rate for providing a deposition species;
flowing an etchant gas into the processing volume at an etchant flow rate for providing an etch species;
providing a high frequency radio frequency (RF) power to the processing volume to generate and maintain a RF plasma in the processing volume, wherein the high frequency RF power comprises a frequency of about 10 MHz to about 40 MHz; and
forming a carbon gapfill layer over the at least two features by using the RF plasma to concurrently deposit the deposition species on the substrate and etch the deposited deposition species using the etch species.

2. The method of claim 1, wherein the etch species is hydrogen (H₂).

3. The method of claim 1, wherein etching the deposited deposition species using the etch species includes etching a deposited deposition species on a top surface of the at least two features, the at least two features comprising vertical structures.

4. The method of claim 1, further comprising flowing a dilution gas at a dilution flow rate for providing a dilution species, wherein the dilution gas is helium (He).

5. The method of claim 1, further comprising at least a trench between the at least two features.

6. The method of claim 5, wherein the trench comprises a critical dimension of about 8 nm to about 1000 nm.

7. The method of claim 6, wherein the critical dimension is about 20 nm to about 350 nm.

8. The method of claim 5, wherein the trench comprises an aspect ratio of about 22:1 to about 0.5:1.

9. The method of claim 1, wherein the hydrocarbon precursor gas comprises acetylene (C₂H₂) or propylene (C₃H₆).

10. The method of claim 1, wherein the high frequency RF power comprises an RF power of about 400 W and about 1500 W.

11. The method of claim 1, wherein the high frequency RF power provides a sheath potential of about 100 V to about 150 V.

12. The method of claim 1, wherein the high frequency RF power provides an electron temperature of about 2.2 eV to about 2.5 eV.

13. The method of claim 1, wherein a temperature inside the processing volume is between about 300 degrees Celsius and about 600 degrees Celsius.

14. The method of claim 1, wherein a pressure inside the processing volume is between about 1 Torr and about 10 Torr.

15. A method of forming a carbon gapfill layer comprising:
positioning a substrate having a top surface with at least two features disposed thereon on a substrate support in a processing volume of a process chamber;
flowing a deposition species into the processing volume;
flowing an etch species into the processing volume;
providing a high frequency RF power to the processing volume to generate and maintain a RF plasma in the processing volume, wherein the high frequency RF power comprises a frequency of about 10 MHz to about 40 MHz; and
forming a carbon gapfill layer over the at least two features by using the RF plasma to concurrently deposit the deposition species on the substrate and etch the deposited deposition species using the etch species; and
maintaining the RF plasma for a time period to form the carbon gapfill layer in a trench between the at least two features having a maximum vertical height difference of about 1 nm to about 10 nm.

16. The method of claim 15, wherein the trench comprises a critical dimension of about 8 nm to about 1000 nm.

17. The method of claim 16, wherein the trench comprises an aspect ratio of about 22:1 to about 0.5:1.

18. The method of claim 17, wherein the high frequency RF power provides a sheath potential of about 100 V to about 150 V.

19. The method of claim 15, wherein the high frequency RF power provides an electron temperature of about 2.2 eV to about 2.5 eV.

20. A method for forming a carbon gapfill layer, comprising:
positioning a substrate having a top surface with at least two features disposed thereon on a substrate support in a processing volume of a process chamber;
flowing a hydrocarbon precursor gas into the processing volume at a precursor flow rate for providing a deposition species;
flowing an etchant gas into the processing volume at an etchant flow rate for providing an etch species;
providing a high frequency radio frequency (RF) power to the processing volume to generate and maintain a RF plasma in the processing volume, wherein the high frequency RF power comprises a frequency of about 10 MHz to about 40 MHz; and
forming a carbon gapfill layer over the at least two features by using the RF plasma to concurrently deposit the deposition species on the substrate and etch the deposited deposition species, wherein etching the deposited deposition species using the etch species includes etching a deposited deposition species on a top surface of the at least two features.
